(19) United States
(12) Patent Application Publication
(10) Pub. No.: US 2013/0183801 A1
(43) Pub. Date: Jul. 18, 2013

(54) METHOD FOR MANUFACTURING SEMICONDUCTOR DEVICES

(71) Applicants: Tsung-Min Kuo, Tainan City (TW); Feng-Mou Chen, Tainan City (TW); Wei-Che Chen, Kaohsiung City (TW); Chun-Chieh Fang, Tainan City (TW)

(72) Inventors: Tsung-Min Kuo, Tainan City (TW); Feng-Mou Chen, Tainan City (TW); Wei-Che Chen, Kaohsiung City (TW); Chun-Chieh Fang, Tainan City (TW)

(21) Appl. No.: 13/352,347

(22) Filed: Jan. 18, 2012

(51) Int. Cl. H01L 21/8234

(52) U.S. Cl. 438/275; 257/E21.616; 257/E21.619

(57) ABSTRACT

A method for manufacturing semiconductor devices includes providing a substrate having a first region and a second region defined thereon, and a shallow trench isolation (STI) formed in between the first region and the second region, the first region comprising a first gate structure and the second region comprising a second gate structure respectively formed therein; forming a patterned protecting layer covering at least the entire STI and the second region on the substrate; forming recesses not exposing the STI in the substrate respectively at two sides of the first gate structure; and forming an epitaxial layer in the recesses respectively, the epitaxial layer filling up the recesses.

### BACKGROUND OF THE INVENTION

1. Field of the Invention

The invention relates to a method for manufacturing semiconductor devices, and more particularly, to a method for manufacturing semiconductor devices applied with strained-silicon technique.

2. Description of the Prior Art

With semiconductor processes entering the era of the deep submicron meter below 65 nanometer (nm), it has been more and more important to increase drive current of the metal-oxide semiconductor (hereinafter abbreviated as MOS) transistor. To improve device performance, strained-silicon technique such as selective epitaxial growth (hereinafter abbreviated as SEG) method is developed to form epitaxial layers serving as the source/drain of the MOS transistor. Because a lattice constant of the epitaxial layer is different from that of silicon, such characteristic is employed to cause alteration to the band structure of the silicon in the channel region. Accordingly, carrier mobility of the channel region of the MOS transistor is enhanced and thus device performance is improved.

The semiconductor device applied with SEG method in the prior art is to form recesses in the substrate respectively at two sides of the gate structure, and followed by forming an epitaxial layer in each recess. The epitaxial layer serves as the source/drain by performing ion implantation before, during, or after the SEG method. Accordingly, carrier mobility of a channel region which is formed between the source/drain and underneath the gate structure is improved because the epitaxial layers in the source/drain region render compressive or tensile stress to the channel region.

However, as size of the semiconductor device keeps shrinking, the stress provided by the epitaxial layer is more and more susceptible to shapes, configuration, and material choice of itself. Furthermore, it is well-known that the epitaxial layer is formed along the surface of the recess during the SEG method; therefore shapes and crystalline orientation of each surface of the recess also render impacts to the epitaxial layer greatly. For example, it is found the epitaxial layer cannot be formed as expected at interface between the silicon and insulating material such as shallow trench isolation (hereinafter abbreviated as STI) or between the silicon and air. Consequently, the epitaxial layer is apt lean on the epitaxial body itself and is resulted in an undesirable faceted shape. That is, an epitaxy loss problem is generated. More serious, the epitaxy loss problem causes stress loss, which means carrier mobility of the semiconductor device cannot be improved as expected due to the insufficient stress supplied to the channel region.

Therefore, there is still a need for a method for manufacturing a semiconductor device that is able to improve result of the SEG method and to obtain the epitaxial layers as expected.

### SUMMARY OF THE INVENTION

According to an aspect of the present invention, a method for manufacturing semiconductor devices is provided. The method first provides a substrate having a first region and a second region defined thereon, and a shallow trench isolation (STI) formed between the first region and the second region, the first region comprising a first gate structure and the second region comprising a second gate structure respectively formed therein. Next, the method includes forming a patterned protecting layer covering at least the entire STI and the second region on the substrate, forming recesses not exposing the STI in the substrate respectively at two sides of the first gate structure, and forming an epitaxial layer in the recesses respectively, the epitaxial layer filling up the recesses.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 are drawings illustrating a manufacturing method for semiconductor devices provided by a first preferred embodiment of the present invention, wherein

FIG. 2 is a schematic drawing in a step subsequent to FIG. 1,

FIG. 3 is a schematic drawing in a step subsequent to FIG. 2, and

FIG. 4 is a schematic drawing in a step subsequent to FIG. 3.

FIGS. 5-8 are drawings illustrating a manufacturing method for semiconductor devices provided by a second preferred embodiment of the present invention, wherein

FIG. 6 is a schematic drawing in a step subsequent to FIG. 5,

FIG. 7 is a schematic drawing in a step subsequent to FIG. 6, and

FIG. 8 is a schematic drawing in a step subsequent to FIG. 7.

FIG. 9 is a piecewise linear graph depicting comparison between the semiconductor devices obtained by the method of the present invention and by the prior art.

### DETAILED DESCRIPTION

Please refer to FIGS. 1-4, which are drawings illustrating a method for manufacturing semiconductor devices provided by a first preferred embodiment of the present invention. As shown in FIG. 1, the preferred embodiment first provides a substrate 100 including a first semiconductor material, such as silicon. The substrate 100 further includes a first region 102 and a second region 104 defined thereon, and a STI 106 is formed between the first region 102 and the second region 104 for providing electrical isolation. The preferred embodiment further provides a first gate structure 122 formed in the first region 102 and a second gate structure 124 formed in the second region 104 respectively. The first gate structure 122 and the second gate structure 124 include a gate dielectric layer 110, a gate electrode 112a/112b, and a cap layer 114 sequentially and upwardly stacked on the substrate 100. It is well-known to those skilled in the art that the cap layer 114 is formed to cover the gate electrode 112a/112b to protect the gate electrode 112a/112b from damage that may be caused in any process such as photolithograph process, ion implantation, etching process, or any needed cleaning process in the semiconductor fabricating process. According to the preferred embodiment, the first gate structure 122 is a gate structure for a pMOS transistor device and the second gate structure 124 is a gate structure for an nMOS transistor device.

Please still refer to FIG. 1. Next, a spacer 130 is formed on sidewalls of the first gate structure 122 and the second gate structure 124, respectively. Subsequently, different ion implantations are performed to form first lightly-doped drains (LDDs) 132 in the substrate 100 respectively at two sides of the first gate structure 112 and to form second LDDs 134 in the substrate 100 respectively at two sides of the second gate structure 124. The spacer 130 preferably is a multi-layered structure including an L-shaped seal layer and an insulating layer covering the seal layer. The spacer 130 formed on the sidewalls of the first gate structure 122 and the second gate structure 124 is used to protect the sidewalls of the first gate structure 122 and the second gate structure 124 and to define positions for forming the source/drain. It is well-known to those skilled in the art that dopants for forming the LDDs 132/134 are laterally diffused to the substrate 100 under the spacers 130 of the first gate structure 122 and of the gate structure 124 by anneal treatment.

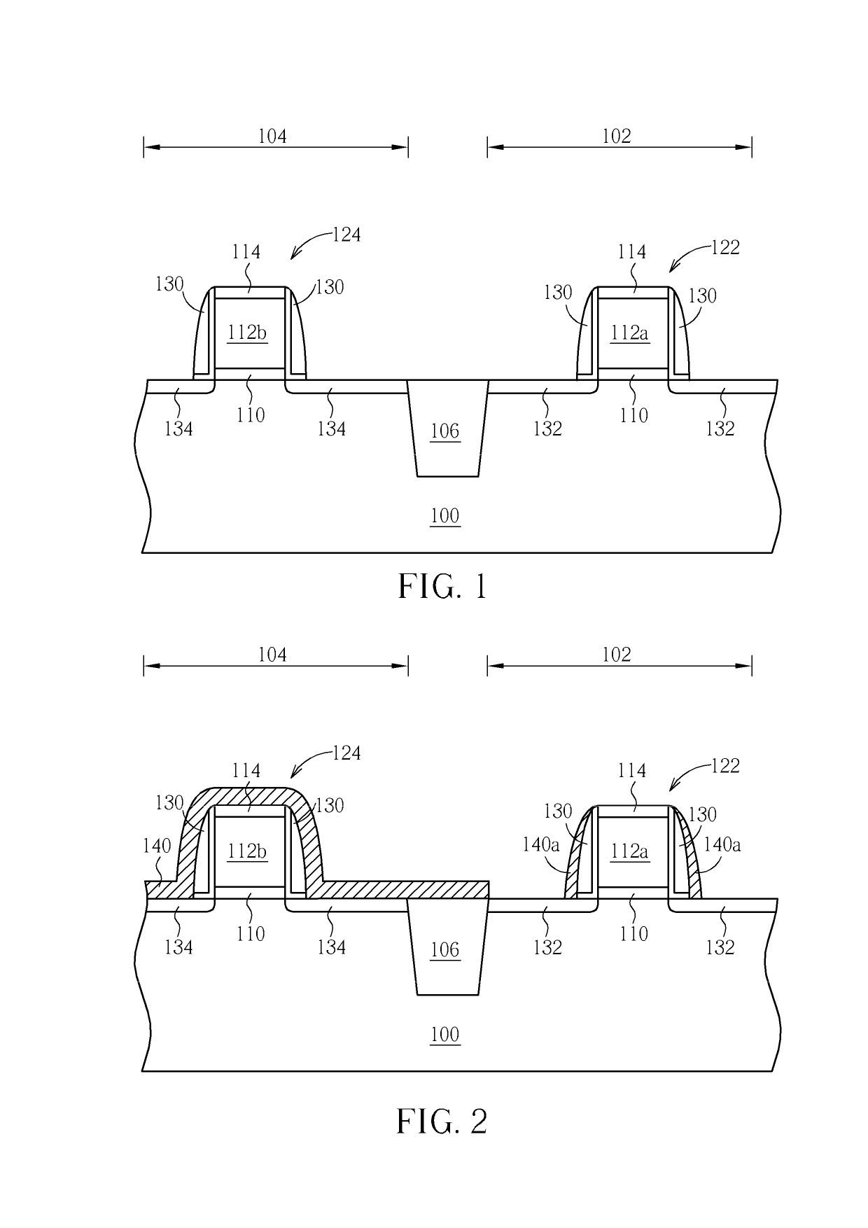

Please refer to FIG. 2. Then, a protecting layer is formed on the substrate 100. According to the preferred embodiment, the protecting layer can include silicon nitride, but not limited to this. Subsequently, a patterning step is performed to remove a portion of the protecting layer to form a patterned protecting layer 140 on the substrate 100. Simultaneously, a disposal spacer 140a is formed on the spacer 130 in the first region 102. It is noteworthy that the patterned protecting layer 140 covers the entire STI 106 and the entire second region 104.

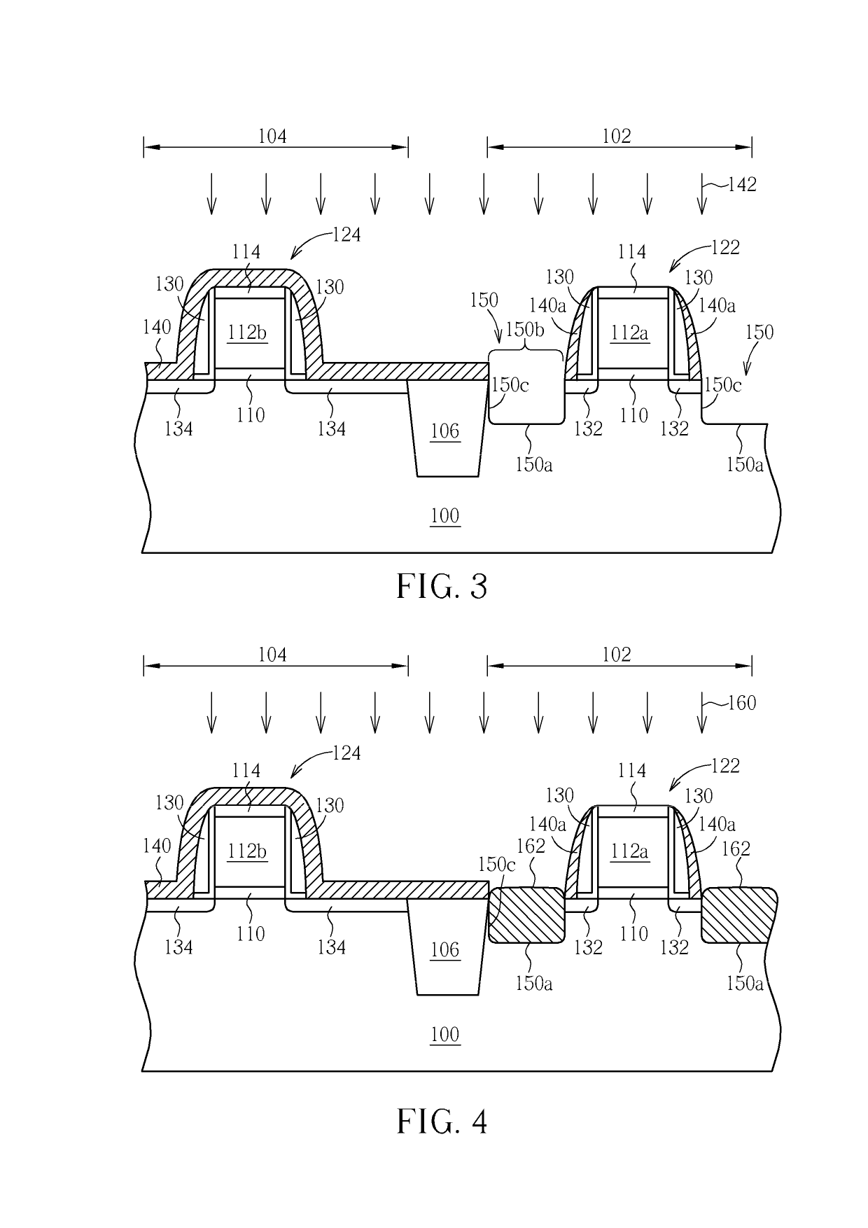

Please refer to FIG. 3. After forming the patterned protecting layer 140 and the disposal spacer 140a, a vertical etching process 142 is performed to anisotropically etch the substrate 100 at the two sides of the first gate structure 122. During the vertical etching process 142, the cap layer 114, the disposal spacer 140a of the first gate structure 122 in the first region 102, and the patterned protecting layer 140 covering the entire second region 104 and STI 106 serve as an etching mask. Thus, a recess 150 is formed in the substrate 100 respectively at two sides of the first gate structure 122. It is noteworthy that since the recess 150 is etched by the anisotropic vertical etching process 142, the recess 150 obtains a flat bottom 150a, an opening 150b, and sidewalls 150c connecting the bottom 150a and the opening 150b. More important, since the recess 150 is formed by the vertical process 142, the STI 106 is not exposed in the sidewalls 150c of the recess 150 as shown in FIG. 3. In other words, the bottoms 150a and the sidewalls 150c of the recess 150 both include homogenous silicon material.

Please refer to FIG. 4. Next, a SEG method 160 is performed to form an epitaxial layer 162 filling up each recess 150. It is well-known to those skilled in the art that in the SEG method 160, the epitaxial layer 162 is to grow along each surface of the recess 150, therefore the epitaxial layer 162 is formed along the surface of the bottom 150a and the sidewalls 150c of the recess 150 in the preferred embodiment. It is noteworthy that the epitaxial layer 162 formed along the flat bottom 150a obtains a flat bottom, and the flat bottom of the epitaxial layer 162 avoids the device leakage that always occurs when the epitaxial layer has the V-shaped pointed end. Furthermore, the epitaxial layer 162 includes the first semiconductor material as mentioned above and a second semiconductor material, and the second semiconductor material is chosen from different material depending on requirements to the conductivity types. When the epitaxial layer 162 is an element for a pMOS transistor, the second semiconductor material includes semiconductor materials of which the lattice constant is larger than the lattice constant of silicon, such as germanium. When the epitaxial layer 162 is an element for an nMOS transistor, the second semiconductor material includes semiconductor materials of which the lattice constant is smaller than the lattice constant of silicon, such as carbon. In other words, the epitaxial layer 162 can include SiGe or SiC according to the requirements to different conductivity types. In addition, ion implantation can be performed before, during, or after the SEG method 160, and thus a first source/drain is obtained. Additionally, the patterned protecting layer 140 is selectively removed and followed by performing a silicide process to form silicide (not shown) at least on the surface of the epitaxial layers 162.

According to method for manufacturing semiconductor devices provided by the preferred embodiment, the patterned protecting layer 140 is formed to cover the entire STI 106 and the second region 104. Therefore, the STI 106 is not exposed in the recesses 150. In other words, the epitaxial layers 162 are formed in a homogenous silicon environment and the expected shapes are obtained. Therefore, the epitaxial layers 162 with desirable shape are able to provide sufficient stress to the channel region and thus performances of the semiconductor devices are improved.

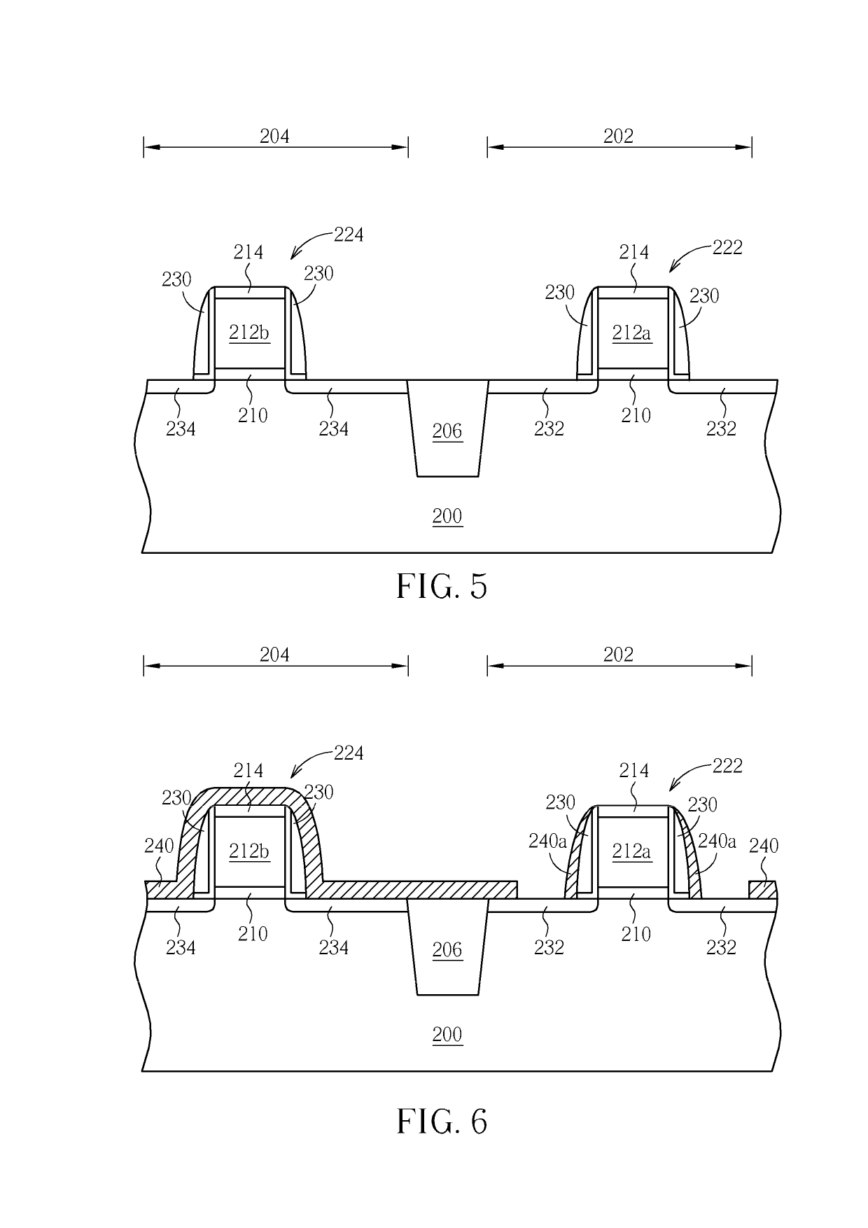

Please refer to FIGS. 5-8, which are drawings illustrating a method for manufacturing semiconductor devices provided by a second preferred embodiment of the present invention. As shown in FIG. 5, the preferred embodiment first provides a substrate 200 including a first semiconductor material, such as silicon. The substrate 200 further includes a first region 202 and a second region 204 defined thereon, and a STI 206 is formed between the first region 202 and the second region 204 for providing electrical isolation. The preferred embodiment further provides a first gate structure 222 formed in the first region 202 and a second gate structure 224 formed in the second region 204. The first gate structure 222 and the second gate structure 224 include a gate dielectric layer 210, a gate electrode 212a/212b, and a cap layer 214 sequentially and upwardly stacked on the substrate 200. According to the preferred embodiment, the first gate structure 222 is a gate structure for a pMOS transistor device and the second gate structure 224 is a gate structure for an nMOS transistor device.

Please still refer to FIG. 5. Next, a spacer 230 is formed on sidewalls of the first gate structure 222 and the second gate structure 224, respectively. Subsequently, different ion implantations are performed to form first LDDs 232 in the substrate 200 respectively at two sides of the first gate structure 212 and to form second LDDs 234 in the substrate 200 respectively at two sides of the second gate structure 224.

Please refer to FIG. 6. Then, a protecting layer is formed on the substrate 200. According to the preferred embodiment, the protecting layer can include silicon nitride, but not limited to this. Subsequently, a patterning step is performed to remove a portion of the protecting layer to form a patterned protecting layer 240 on the substrate 200. Simultaneously, a disposal spacer 240a is formed on the spacer 230 in the first region 202. It is noteworthy that the patterned protecting layer 240 not only covers the entire STI 206 and the entire second region 204, but also covers a portion of the first region 202 in the preferred embodiment.

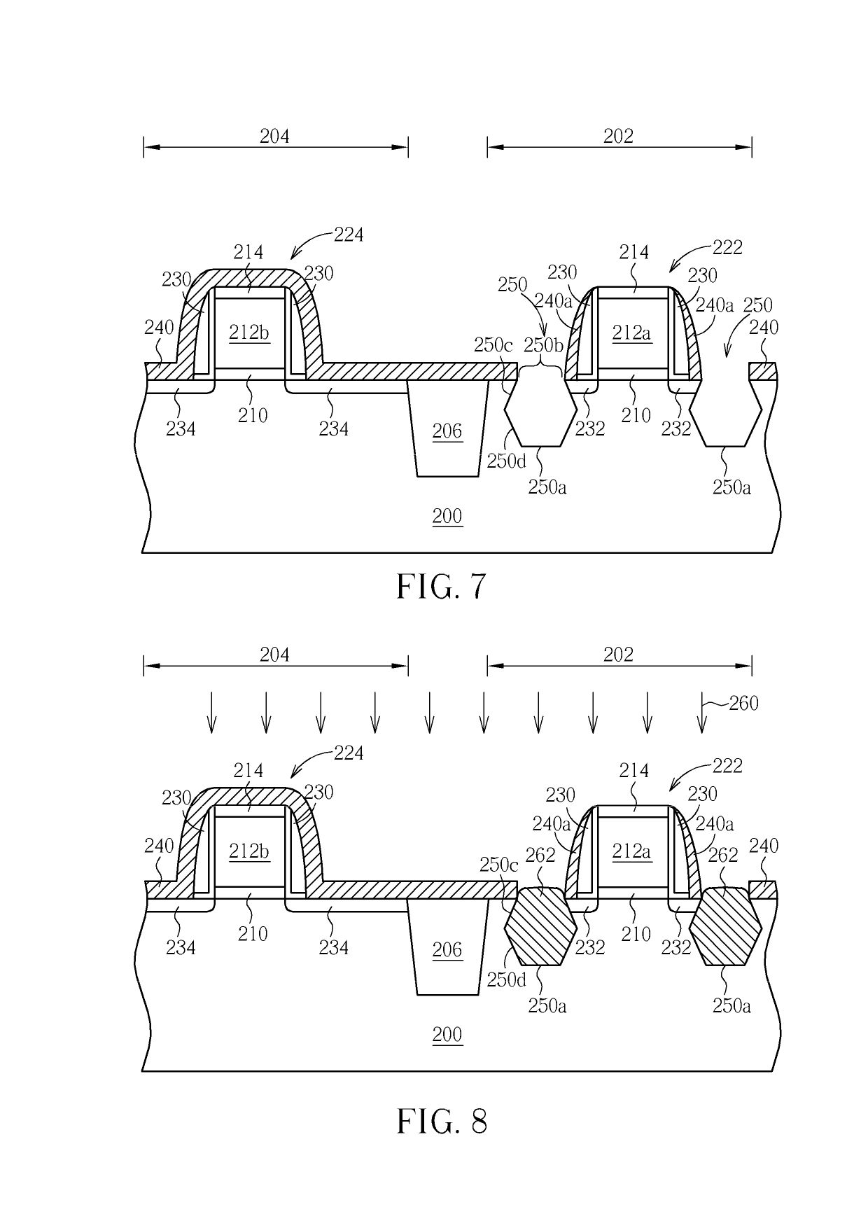

Please refer to FIG. 7. After forming the patterned protecting layer 240 and the disposal spacer 240a, a vertical etching process and a later etching process are sequentially performed to anisotropically etch the substrate 200 at the two sides of the first gate structure 222. During the vertical etching process and the lateral etching process, the cap layer 214 and the disposal spacer 240a of the first gate structure 222 in the first region 202, and the patterned protecting layer 240 covering the entire second region 204 and STI 206 and the portion of the first region 202 serve as an etching mask. Thus, a recess 250 is formed in the substrate 200 respectively at two sides of the first gate structure 222. It is noteworthy that since the recess 250 is etched by the anisotropic vertical etching process and the lateral etching process, the recess 250 obtains a flat bottom 250a, an opening 250b, first slanted sidewalls 250c connecting to the bottom 250a, and second slanted sidewalls 250d connecting the first slanted sidewalls 250c and the bottom 250a. In other words, by sequentially performing the vertical etching process and the lateral etching process, hexagonal recesses 250 are obtained. More important, since the patterned protecting layer 240 covers the portion of the first region 202, the STI 206 is protected by the patterned protecting layer 240 during the etching processes. In addition, by adjusting the process duration and the etchant concentration, the preferred embodiment is able to ensure that the STI 206 is not exposed in the first slanted sidewalls 250c and the second slanted sidewalls 250d as shown in FIG. 7. In other words, the bottom 250a, the first slanted sidewalls 250c, and the second slanted sidewalls 250d of the recess 250 all include homogenous silicon material.

Please refer to FIG. 8. Next, a SEG method 260 is performed to form an epitaxial layer 262 filling up each recess 250. It is well-known to those skilled in the art that in the SEG method 260, the epitaxial layer 262 is to grow along each surface of the recess 250; therefore the epitaxial layer 262 is formed along the bottom surface 250a, the first slanted sidewalls 250c and the second slanted sidewalls 250d of the recess 250 in the preferred embodiment. It is noteworthy that the epitaxial layer 262 formed along the flat bottom 250a obtains a flat bottom, and the flat bottom of the epitaxial layer 262 avoids the device leakage that always occurs when the epitaxial layer has the V-shaped pointed end. Furthermore, the epitaxial layer 262 formed in the recesses 250 obtains hexagonal shape and a pointed end toward the channel region, and thus effective stress provided by the epitaxial layer 262 to the channel region is enhanced. In addition, the epitaxial layer 262 can include SiGe or SiC as mentioned above. After forming the epitaxial layers 262, the patterned protecting layer 240 is selectively removed and followed by performing a silicide process to form silicide (not shown) at least on the surface of the epitaxial layers 262.

According to method for manufacturing semiconductor devices provided by the preferred embodiment, the patterned protecting layer 240 is formed to cover the entire STI 206 and the second region 204, further to cover the portion of the first region 202. Therefore, the STI 206 is not exposed in the recesses 250 having special shape. In other words, the epitaxial layers 262 are formed in the homogenous silicon environment and thus the expected shapes are obtained. Therefore, the epitaxial layers 262 with desirable shape are able to provide sufficient stress to the channel region and thus performances of the semiconductor devices are improved.

According to the method for manufacturing semiconductor device provided by the present invention, when the patterned protecting layer 140/240 covers the entire STI 106/206, the vertical etching process is used; and when the patterned protecting layer 140/240 covers not only STI 106/206 but also the first region 102/202, vertical and lateral etching processes are used to form the recess 150/250. According to the present invention, different etching processes are involved depending on the ranges the patterned protecting layer 140/240 covers, in order to prevent the STI 106/206 from being exposed in the recess 150/250.

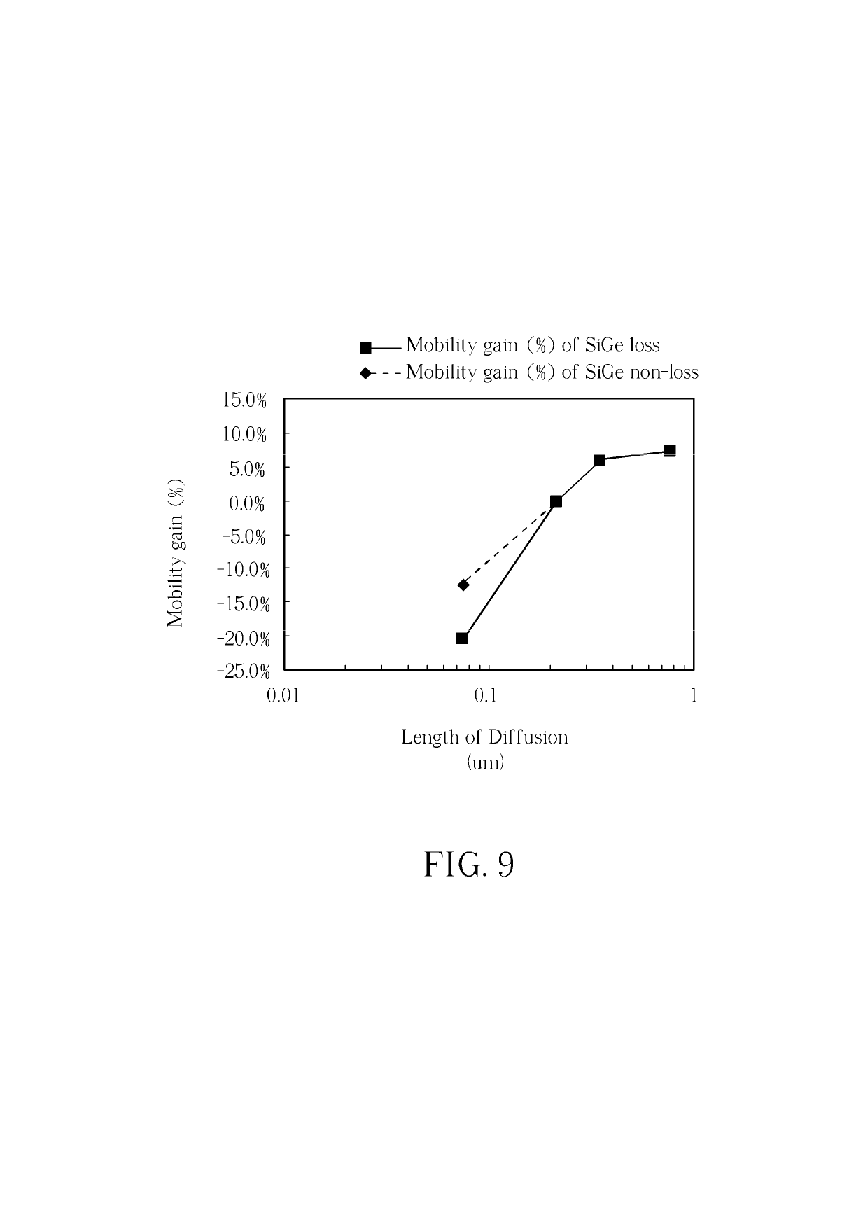

Furthermore, it is well-known that the epitaxy loss and stress loss problem are more serious with the shrinking device size. Therefore, the method for manufacturing semiconductor device provided by the present invention is more preferably used to form device having length of diffusion smaller than 0.25 micrometer (μm). Please refer to FIG. 9, which is a piecewise linear graph depicting comparison between the semiconductor devices obtained by the method of the present invention and by the prior art. As shown in FIG. 9, it is observed that when the length of diffusion is smaller than 0.1 micrometer (μm), the carrier mobility gain of the semiconductor device having epitaxy loss is less than 5% while the carrier mobility gain of the semiconductor device formed by the method of the present invention is about 10% because the epitaxial layer 162/262 is grown in the homogenous silicon environment and no epitaxy loss occurs. Accordingly, the method for manufacturing semiconductor device provided by the present invention is able to solve the epitaxy loss problem and to improve the performance of the semiconductor devices.

According to the method for manufacturing semiconductor devices provided by the present invention, the patterned protecting layer is formed to cover the entire STI. Therefore, the STI is not exposed in the recesses after performing the etching process for forming the recesses. In other words, the epitaxial layers are formed in the homogenous silicon environment. Accordingly, the present invention protects the growth of the epitaxial layer from non-silicon materials, which renders adverse impact to the epitaxy growth. Therefore, the epitaxial layers are obtained as expected and thus are able to provide sufficient stress to the channel region. Consequently, performances of the semiconductor devices are improved.

Those skilled in the art will readily observe that numerous modifications and alterations of the device and method may be made while retaining the teachings of the invention. Accordingly, the above disclosure should be construed as limited only by the metes and bounds of the appended claims.

1. A method for manufacturing semiconductor devices comprising:
providing a substrate having a first region and a second region defined thereon, and a shallow trench isolation (STI) formed between the first region and the second region, the first region comprising a first gate structure and the second region comprising a second gate structure respectively formed therein;
forming a patterned protecting layer covering at least the entire STI and the second region on the substrate;
forming recesses in the substrate respectively at two sides of the first gate structure, entire top surface of the STI being not exposed by the recesses; and
forming an epitaxial layer in the recesses respectively, the epitaxial layer filling up the recesses.

2. The method for manufacturing semiconductor devices according to claim 1, further comprising:
forming first lightly-doped drains (LDDs) in the substrate respectively at two sides of the first gate structure and second LDDs in the substrate respectively at two sides of the second gate structure; and
forming a spacer on sidewalls of the first gate structure and the second gate structure, respectively.

3. The method for manufacturing semiconductor devices according to claim 1, wherein the patterned protecting layer comprises silicon nitride.

4. The method for manufacturing semiconductor devices according to claim 1 further comprising forming a disposal spacer on the first gate structure simultaneously with forming the patterned protecting layer.

5. The method for manufacturing semiconductor devices according to claim 1, further comprising performing a vertical etching process to formed the recesses.

6. The method for manufacturing semiconductor device according to claim 1, wherein the patterned protecting layer further covers a portion of the first region.

7. The method for manufacturing semiconductor devices according to claim 6, further comprising sequentially performing a vertical etching process and a lateral etching process to form the recesses.

8. The method for manufacturing semiconductor devices according to claim 7, wherein the recess comprises a bottom, an opening, a first slanted sidewall connecting the opening, and a second slanted sidewall connecting the first slanted sidewall and the bottom.

9. The method for manufacturing semiconductor devices according to claim 1, wherein the substrate comprises a first semiconductor material.

10. The method for manufacturing semiconductor devices according to claim 9, wherein the epitaxial layer comprises the first semiconductor material and a second semiconductor material.

11. The method for manufacturing semiconductor devices according to claim 10, wherein a lattice constant of the first semiconductor material is smaller than a lattice constant of the second semiconductor material.
